(19) United States
(12) Patent Application Publication
(10) Pub. No.: US 2024/0260387 A1
(43) Pub. Date: Aug. 1, 2024

(54) DISPLAY DEVICE

(71) Applicant: LG Display Co., Ltd., Seoul (KR)

(72) Inventor: DongYoon KIM, Seongnam-si (KR)

(21) Appl. No.: 18/490,527

(22) Filed: Oct. 19, 2023

(30) Foreign Application Priority Data
Jan. 31, 2023 (KR) 10-2023-0013243

(51) Int. Cl. H10K 59/80; H10K 59/122; H10K 59/131

(52) U.S. Cl. CPC H10K 59/80; H10K 59/122; H10K 59/131; H10K 2102/311

(57) ABSTRACT

According to an aspect of the present disclosure, a display device includes: a first substrate having a display area including a plurality of subpixels, and a non-display area; at least one flexible film at one end of the non-display area of the first substrate and electrically connected to the first substrate; a bonding member on the first substrate, including a conductive adhesive material, and bonding the first substrate and the flexible film; a second substrate above the first substrate, configured to expose the flexible film and the bonding member to the outside, and including a metallic material; an adhesive layer between the first substrate and the second substrate; and a blocking film on a lower surface of the second substrate and including an insulating material. Therefore, it is possible to suppress a leakage current that may occur due to the contact of the bonding member and the second substrate at the time of bonding the flexible film to the first substrate.

### CROSS-REFERENCE TO RELATED APPLICATIONS

This application claims the priority of Korean Patent Application No. 10-2023-0013243 filed on Jan. 31, 2023, in the Korean Intellectual Property Office, the disclosure of which is incorporated herein by reference.

### BACKGROUND

### Technical Field

The present disclosure relates to a display device, and more particularly, to a display device that may allow a laser lift-off (LLO) process to be easily performed and suppress the occurrence of leakage current.

### Description of the Related Art

As display devices used for a monitor of a computer, a TV set, a mobile phone, and the like, there are an organic light-emitting display (OLED) configured to autonomously emit light, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a flexible display device, which is made by forming display elements, lines, and the like on a substrate made of a flexible plastic material having flexibility and thus may display images even when being folded or rolled up, has attracted attention as a next-generation display device.

### BRIEF SUMMARY

The present disclosure provides a display device that uses a substrate made of transparent conducting oxide, oxide semiconductor, or silicone, instead of a plastic substrate, and allows an LLO process to be easily performed.

The present disclosure provides a display device that minimizes the occurrence of a leakage current.

The present disclosure provides a display device with improved driving reliability.

Technical benefits, features, and functions of the present disclosure are not limited to those above-mentioned, and other benefits, features, and functions, which are not mentioned above, can be clearly understood by those skilled in the art from the following descriptions.

According to an aspect of the present disclosure, a display device includes: a first substrate having a display area including a plurality of subpixels, and a non-display area; at least one flexible film at one end of the non-display area of the first substrate and electrically connected to the first substrate; a bonding member on the first substrate, including a conductive adhesive material, and bonding the first substrate and the flexible film; a second substrate above the first substrate, configured to expose the flexible film and the bonding member to the outside, and including a metallic material; an adhesive layer between the first substrate and the second substrate; and a blocking film on a lower surface of the second substrate and including an insulating material. Therefore, the display device according to the example embodiment of the present disclosure may facilitate the LLO process and suppress a leakage current.

Other detailed matters of the example embodiments are included in the detailed description and the drawings.

According to the present disclosure, the bonding member for bonding the first substrate and the flexible film is positioned inward of an end of the first substrate, which facilitates an LLO process.

According to the present disclosure, the blocking film, which is made of an insulating material, is disposed on the lower surface of the second substrate facing the first substrate, and the blocking film is disposed to correspond to a position of the bonding member disposed on the first substrate. Therefore, it is possible to suppress a leakage current that may occur between the second substrate and the bonding member as the bonding member is spread at the time of bonding the flexible film to the first substrate.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a top plan view of a display device according to an example embodiment of the present disclosure;

FIG. 2 is a circuit diagram of a subpixel of the display device according to the example embodiment of the present disclosure;

FIG. 3 is an enlarged top plan view of the display device according to the example embodiment of the present disclosure;

FIG. 4 is a cross-sectional view taken along line IV-IV′ in FIG. 3;

FIG. 5A is a cross-sectional view taken along line V-V′ in FIG. 1;

FIG. 5B is a top plan view illustrating a blocking film and a second substrate of the display device according to the example embodiment of the present disclosure;

FIG. 6 is a top plan view illustrating a blocking film and a second substrate of a display device according to another example embodiment of the present disclosure;

FIG. 7 is a cross-sectional view of a display device according to still another example embodiment of the present disclosure;

FIG. 8A is a cross-sectional view of a display device according to yet another example embodiment of the present disclosure;

FIG. 8B is a top plan view illustrating a blocking film and a second substrate of the display device according to still another example embodiment of the present disclosure;

FIGS. 9A and 9B are cross-sectional views of a display device according to yet another example embodiment of the present disclosure;

FIGS. 10A to 10C are top plan views illustrating several examples of arrangements of additional banks of a display device according to still yet another example embodiment of the present disclosure;

FIG. 11 is a cross-sectional view of a display device according to a further example embodiment of the present disclosure; and

FIG. 12 is a cross-sectional view of a display device according to another further example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

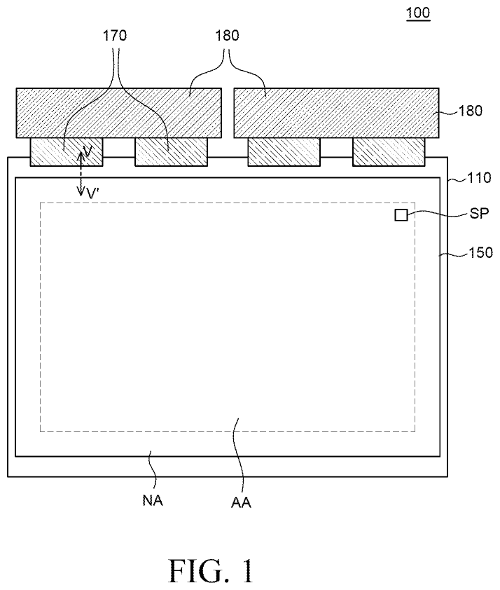

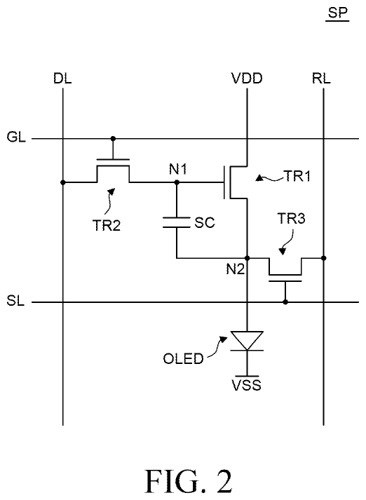

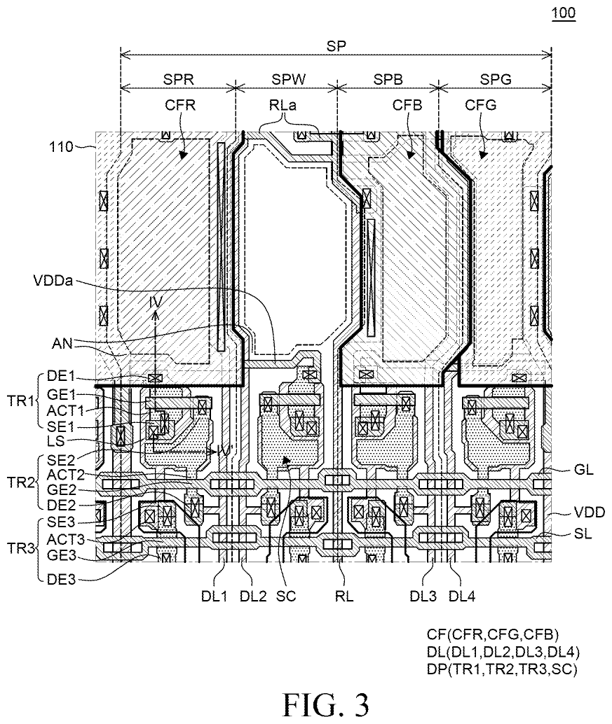

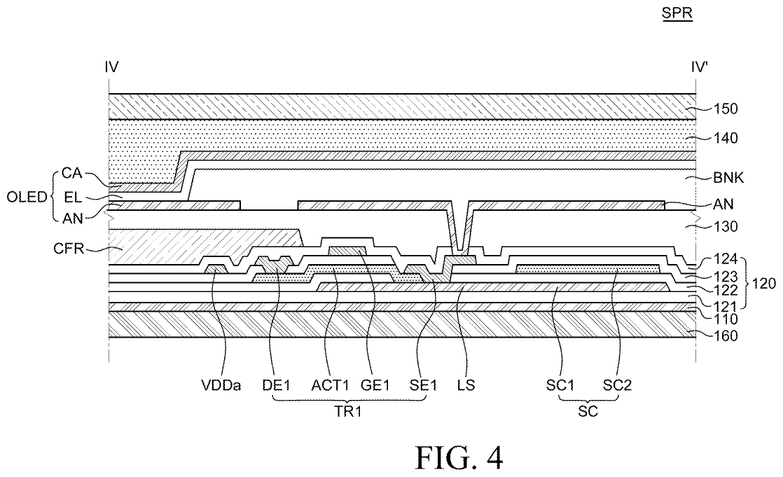

FIG. 1 is a top plan view of a display device according to an example embodiment of the present disclosure. FIG. 2 is a circuit diagram of a subpixel of the display device according to the example embodiment of the present disclosure. FIG. 3 is an enlarged top plan view of the display device according to the example embodiment of the present disclosure. FIG. 4 is a cross-sectional view taken along line IV-IV′ in FIG. 3. For convenience of description, FIG. 1 illustrates only a first substrate 110, a second substrate 150, a plurality of flexible films 170, and plurality of printed circuit boards 180 among various constituent elements of a display device 100. More specifically, FIG. 3 is an enlarged top plan view of a red subpixel SPR, a white subpixel SPW, a blue subpixel SPB, and a green subpixel SPG that constitute a single pixel. For convenience of description, FIG. 3 does not illustrate a bank BNK, and rims of a plurality of color filters CF are indicated by a bold solid line.

With reference to FIGS. 1 to 4, the first substrate 110 is a support member for supporting the other constituent elements of the display device 100. The first substrate 110 may be made of any one of a transparent conducting oxide and an oxide semiconductor. The oxide semiconductor may be a transparent oxide semiconductor.

For example, the transparent conducting oxide, which constitutes the first substrate 110, may be a material such as indium tin oxide (ITO), indium zinc oxide (IZO), or indium tin zinc oxide (ITZO).

In addition, the oxide semiconductor, which constitutes the first substrate 110, may contain indium (In) and gallium (Ga), for example, a transparent oxide semiconductor such as indium-gallium-zinc oxide (IGZO), indium gallium oxide (IGO), and indium-tin-zinc oxide (ITZO).

However, the materials and types of transparent conducting oxides and oxide semiconductors are exemplarily provided. The first substrate 110 may be made of other transparent conducting oxide and oxide semiconductor materials that are not disclosed in the present specification. However, the present disclosure is not limited thereto.

Meanwhile, the first substrate 110 may be formed by depositing the transparent conducting oxide or oxide semiconductor with a very small thickness. Therefore, the first substrate 110 may have flexibility as the first substrate 110 has a very small thickness. Further, the display device 100 including the first substrate 110 having flexibility may be implemented as the flexible display device 100 that may display images even though the display device 100 is folded or rolled up. For example, in a case in which the display device 100 is a foldable display device, the first substrate 110 may be folded or unfolded about a folding axis. As another example, in a case in which the display device 100 is a rollable display device, the display device may be rolled up around a roller and stored. Therefore, the display device 100 according to the example embodiment of the present disclosure may be implemented as the flexible display device 100 such as a foldable display device or a rollable display device by using the first substrate 110 having flexibility.

Meanwhile, the display device 100 may be a top-emission type display device or a bottom-emission type display device depending on a direction in which light is emitted from a light-emitting element OLED.

The top-emission type display device allows the light emitted from the light-emitting element to propagate toward an upper side of the first substrate 110 on which the light-emitting element OLED is disposed. The top-emission type display panel may have a reflective layer formed on a lower portion of an anode AN in order to allow the light emitted from the light-emitting element OLED to propagate toward the upper side of the first substrate 110, i.e., toward a cathode CA.

The bottom-emission type display panel allows the light emitted from the light-emitting element OLED to propagate toward a lower side of the first substrate 110 on which the light-emitting element OLED is formed. In the case of the bottom-emission type display panel, the anode AN may be made of only a transparent electrically conductive material and the cathode CA may be made of a metallic material with high reflectance in order to allow the light emitted from the light-emitting element OLED to propagate toward the lower side of the first substrate 110.

Hereinafter, for the convenience of description, the display device 100 according to the example embodiment of the present disclosure will be described as being the bottom-emission type display device. However, the present disclosure is not limited thereto.

Referring to FIG. 1, the first substrate 110 includes a display area AA and a non-display area NA.

The display area AA is an area in which images are displayed. A plurality of subpixels SP may be disposed in the display area AA to display images.

With reference to FIG. 3, the plurality of subpixels SP include a red subpixel SPR, a green subpixel SPG, a blue subpixel SPB, and a white subpixel SPW. For example, the red subpixel SPR, the white subpixel SPW, the blue subpixel SPB, and the green subpixel SPG may be sequentially disposed in a row direction. However, the arrangement order of the plurality of subpixels SP is not limited thereto.

Each subpixel of the plurality of subpixels SP includes a light-emitting area EA and a circuit area CA. The light-emitting area EA is an area that may independently emit light with a single type of color. The light-emitting element OLED may be disposed in the light-emitting area. Specifically, the light-emitting area EA may be referred to as an area exposed from the bank and configured such that the light emitted from the light-emitting element OLED may propagate to the outside among the areas in which the plurality of color filters CF and the anode AN overlap one another. For example, with reference to FIGS. 2 and 4 together, the light-emitting area EA of the red subpixel SPR may be an area exposed from the bank BNK in an area in which a red color filter CFR and the anode AN overlap each other. The light-emitting area EA of the green subpixel SPG may be an area exposed from the bank BNK in an area in which a green color filter CFG and the anode AN overlap each other. The light-emitting area EA of the blue subpixel SPB may be a blue light-emitting area that emits blue light in an area exposed from the bank BNK in an area in which a blue color filter CF and the anode AN overlap each other. In this case, the light-emitting area EA of the white subpixel SPW in which no separate color filter CF is disposed may be a white light-emitting area that emits white light in an area that overlaps a part of the anode AN exposed from the bank BNK.

The circuit area CA is an area except for the light-emitting area EA. A plurality of lines may be disposed in the circuit area and transmit various types of signals to a drive circuit DP for operating the plurality of light-emitting elements OLED. Further, the circuit area CA in which the drive circuit DP, the plurality of lines, and the bank BNK are disposed may be a non-light-emitting area.

With reference to FIGS. 2 and 3, a drive circuit DP for operating a light-emitting element OLED of each of a plurality of subpixels SP includes a first transistor TR1, a second transistor TR2, a third transistor TR3, and a storage capacitor SC. Further, the bank is disposed on the first substrate 110. A plurality of lines is disposed on the first substrate 110 in order to operate the drive circuit DP and includes a gate line GL, a data line DL, a high-potential power line VDD, a sensing line SL, and a reference line RL.

The first transistor TR1, the second transistor TR2, and the third transistor TR3, which are included in the drive circuit DP of the single subpixel SP, each include a gate electrode, a source electrode, and a drain electrode.

Further, the first transistor TR1, the second transistor TR2, and the third transistor TR3 may each be a P-type thin-film transistor or an N-type thin-film transistor. For example, in the P-type thin-film transistor, positive charges (holes) flow from the source electrode to the drain electrode, such that current may flow from the source electrode to the drain electrode. In the N-type thin-film transistor, negative charges (electrons) flow from the source electrode to the drain electrode, such that current may flow from the drain electrode to the source electrode. Hereinafter, the assumption is made that the first transistor TR1, the second transistor TR2, and the third transistor TR3 may each be the N-type thin-film transistor in which current flows from the drain electrode to the source electrode. However, the present disclosure is not limited thereto.

The first transistor TR1 includes a first active layer, a first gate electrode, a first source electrode, and a first drain electrode. The first gate electrode is connected to a first node N1. The first source electrode is connected to the anode of the light-emitting element OLED. The first drain electrode is connected to the high-potential power line VDD. The first transistor TR1 may be turned on when a voltage of the first node N1 is higher than a threshold voltage. The first transistor TR1 may be turned off when the voltage of the first node N1 is lower than the threshold voltage. Further, when the first transistor TR1 is turned on, drive current may be transmitted to the light-emitting element OLED through the first transistor TR1. Therefore, the first transistor TR1 configured to control the drive current to be supplied to the light-emitting element OLED may be referred to as a driving transistor.

The second transistor TR2 includes a second active layer, a second gate electrode, a second source electrode, and a second drain electrode. The second gate electrode is connected to the gate line GL. The second source electrode is connected to the first node N1. The second drain electrode is connected to the data line DL. The second transistor TR2 may be turned on or off on the basis of a gate voltage from the gate line GL. When the second transistor TR2 is turned on, the first node N1 may be charged with the data voltage from the data line DL. Therefore, the second transistor TR2 configured to be turned on or off by the gate line GL may be referred to as a switching transistor.

The third transistor TR3 includes a third active layer, a third gate electrode, a third source electrode, and a third drain electrode. The third gate electrode is connected to the sensing line SL. The third source electrode is connected to a second node N2. The third drain electrode is connected to the reference line RL. The third transistor TR3 may be turned on or off on the basis of a sensing voltage from the sensing line SL. Further, when the third transistor TR3 is turned on, a reference voltage may be transmitted from the reference line RL to the second node N2 and the storage capacitor SC. Therefore, the third transistor TR3 may be referred to as a sensing transistor.

Meanwhile, FIG. 2 illustrates that the gate line GL and the sensing line SL are separate lines. However, the gate line GL and the sensing line SL may be implemented as a single line. However, the present disclosure is not limited thereto.

The storage capacitor SC is connected between the first gate electrode and the first source electrode of the first transistor TR1. That is, the storage capacitor SC may be connected between the first node N1 and the second node N2. The storage capacitor SC may supply a predetermined drive current to the light-emitting element OLED by maintaining a potential difference between the first gate electrode and the first source electrode of the first transistor TR1 while the light-emitting element OLED emits light. The storage capacitor SC includes a plurality of capacitor electrodes. For example, one of the plurality of capacitor electrodes may be connected to the first node N1, and another capacitor electrode may be connected to the second node N2.

The light-emitting element OLED includes the anode, the light-emitting layer, and the cathode. The anode of the light-emitting element OLED is connected to the second node N2, and the cathode is connected to a low-potential power line VSS. The light-emitting element OLED may emit light by receiving the drive current from the first transistor TR1.

Meanwhile, FIGS. 2 and 3 illustrate that the drive circuit of the subpixel SP of the display device 100 according to the example embodiment of the present disclosure has a 3T1C structure including the three transistors TR1, TR2, TR3 and the single storage capacitor SC. However, the number of transistors, the number of storage capacitors SC, and a connection relationship between the transistor(s) and the storage capacitor(s) may be variously changed in accordance with design. The present disclosure is not limited thereto.

The configuration of the subpixels SP will be described with reference to FIGS. 2 to 4. The subpixels SP each include the first substrate 110, an insulation layer 121, a buffer layer 122, a gate insulation layer 123, a passivation layer 124, an overcoating layer 130, an adhesive layer 140, the second substrate 150, a polarizing plate 160, the first transistor TR1, the second transistor TR2, the third transistor TR3, the storage capacitor SC, the light-emitting element OLED, the gate line GL, the sensing line SL, the data line DL, the reference line RL, the high-potential power line VDD and the plurality of color filters CF.

The insulation layer 121 is disposed on the first substrate 110. The insulation layer 121 may inhibit moisture and/or oxygen penetrating from the outside of the first substrate 110 from being diffused. Moisture transmission properties of the display device 100 may be controlled by controlling a thickness or a layered structure of the insulation layer 121. In addition, the insulation layer 121 inhibits the first substrate 110 made of the transparent conducting oxide or oxide semiconductor from being short-circuited while coming into contact with other components such as a transistor. The insulation layer 121 may be made of an inorganic material, for example, configured as a single layer or a multilayer made of silicon oxide (SiOx) or silicon nitride (SiNx). However, the present disclosure is not limited thereto.

The plurality of high-potential power lines VDD, the plurality of data lines DL, the plurality of reference lines RL, and the light-blocking layer LS are disposed on the insulation layer 121.

The plurality of high-potential power lines VDD, the plurality of data lines DL, the plurality of reference lines RL, and the light-blocking layer LS may be disposed on the same layer on the first substrate 110 and made of the same electrically conductive material. For example, the plurality of high-potential power lines VDD, the plurality of data lines DL, the plurality of reference lines RL, and the light-blocking layer LS may each be made of an electrically conductive material such as copper (Cu), aluminum (Al), molybdenum (Mo), nickel (Ni), titanium (Ti), chromium (Cr), or an alloy thereof. However, the present disclosure is not limited thereto.

The plurality of high-potential power lines VDD are lines for transmitting high power voltages to the plurality of subpixels SP. The plurality of high-potential power lines VDD may extend in the column direction between the plurality of subpixels SP. Two subpixels SP adjacent to each other in the row direction may share a single high-potential power line VDD among the plurality of high-potential power lines VDD. For example, one high-potential power line VDD may be disposed at the left side of the red subpixel SPR and supply the high-potential power voltage to the first transistor TR1 of each of the red subpixel SPR and the white subpixel SPW. The other high-potential power line VDD may be disposed at the right side of the green subpixel SPG and supply the high-potential power voltage to the first transistor TR1 of each of the blue subpixel SPB and the green subpixel SPG.

The plurality of data lines DL includes a first data line DL1, a second data line DL2, a third data line DL3 and a fourth data line DL4 which are lines that extend in the column direction between the plurality of subpixels SP and transmit the data voltages to the plurality of subpixels SP. The first data line DL1 may be disposed between the red subpixel SPR and the white subpixel SPW and transmit the data voltage to the second transistor TR2 of the red subpixel SPR. The second data line DL2 may be disposed between the first data line DL1 and the white subpixel SPW and transmit the data voltage to the second transistor TR2 of the white subpixel SPW. The third data line DL3 may be disposed between the blue subpixel SPB and the green subpixel SPG and transmit the data voltage to the second transistor TR2 of the blue subpixel SPB. The fourth data line DL4 may be disposed between the third data line DL3 and the green subpixel SPG and transmit the data voltage to the second transistor TR2 of the green subpixel SPG.

The plurality of reference lines RL are lines that extend in the column direction between the plurality of subpixels SP and transmit the reference voltage to the plurality of subpixels SP. The plurality of subpixels SP, which constitute a single pixel, may share a single reference line RL. For example, one reference line RL may be disposed between the white subpixel SPW and the blue subpixel SPB and transmit the reference voltage to the third transistor TR3 of each of the red subpixel SPR, the white subpixel SPW, the blue subpixel SPB, and the green subpixel SPG.

With reference to FIGS. 2 and 4, the light-blocking layer LS is disposed on the insulation layer 121. The light-blocking layer LS may be disposed to overlap a first active layer ACT1 of at least the first transistor TR1 among the plurality of transistors TR1, TR2, and TR3 and inhibit the light from entering the first active layer ACT1. If light is emitted to the first active layer ACT1, a leakage current may occur, which may degrade the reliability of the first transistor TR1 that is a driving transistor. In this case, when the light-blocking layer LS made of an opaque electrically conductive material such as copper (Cu), aluminum (Al), molybdenum (Mo), nickel (Ni), titanium (Ti), chromium (Cr), or an alloy thereof is disposed to overlap the first active layer ACT1, the light-blocking layer LS may inhibit the light from entering the first active layer ACT1 from the lower side of the first substrate 110, thereby improving the reliability of the first transistor TR1. However, the present disclosure is not limited thereto. The light-blocking layer LS may be disposed to overlap a second active layer ACT2 of the second transistor TR2 and a third active layer ACT3 of the third transistor TR3.

Meanwhile, the drawings illustrate that the light-blocking layer LS is a single layer. However, the light-blocking layer LS may be provided as a plurality of layers. For example, the light-blocking layer LS may be provided as a plurality of layers disposed to overlap one another with at least any one of the insulation layer 121, the buffer layer 122, the gate insulation layer 123, and the passivation layer 124 interposed therebetween.

The buffer layer 122 is disposed on the plurality of high-potential power lines VDD, the plurality of data lines DL, the plurality of reference lines RL, and the light-blocking layer LS. The buffer layer 122 may reduce penetration of moisture or impurities through the first substrate 110. For example, the buffer layer 122 may be configured as a single layer or multilayer made of silicon oxide (SiOx) or silicon nitride (SiNx). However, the present disclosure is not limited thereto. In addition, the buffer layer 122 may be omitted in accordance with the type of first substrate 110 or the type of transistor. However, the present specification is not limited thereto.

The first transistor TR1, the second transistor TR2, the third transistor TR3, and the storage capacitor SC are disposed on the buffer layer 122 of each of the plurality of subpixels SP.

First, the first transistor TR1 includes the first active layer ACT1, a first gate electrode GE1, a first source electrode SE1, and a first drain electrode DE1.

The first active layer ACT1 is disposed on the buffer layer 122. The first active layer ACT1 may be made of a semiconductor material such as an oxide semiconductor, amorphous silicon, or polysilicon, but the present disclosure is not limited thereto. For example, in the case in which the first active layer ACT1 is made of an oxide semiconductor, the first active layer ACT1 may include a channel area, a source area, and a drain area. The source area and the drain area may be areas having conductivity. However, the present disclosure is not limited thereto.

The gate insulation layer 123 is disposed on the first active layer ACT1. The gate insulation layer 123 may be a layer for insulating the first gate electrode GE1 and the first active layer ACT1 and made of an insulating material. For example, the gate insulation layer 123 may be configured as a single layer or multilayer made of silicon oxide (SiOx) or silicon nitride (SiNx). However, the present disclosure is not limited thereto.

The first gate electrode GE1 is disposed on the gate insulation layer 123 so as to overlap the first active layer ACT1. The first gate electrode GE1 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first source electrode SE1 and the first drain electrode DE1 are disposed on the gate insulation layer 123 and spaced apart from each other. The first source electrode SE1 and the first drain electrode DE1 may be electrically connected to the first active layer ACT1 through a contact hole formed in the gate insulation layer 123. The first source electrode SE1 and the first drain electrode DE1 may be disposed on the same layer and made of the same electrically conductive material as the first gate electrode GE1. For example, the first source electrode SE1, the first drain electrode DE1 and the first gate electrode GE1 may have been manufactured from one and the same layer, for example by deposition and patterning of said layer. However, the present disclosure is not limited thereto. For example, the first source electrode SE1 and the first drain electrode DE1 may be made of copper (Cu), aluminum (Al), molybdenum (Mo), nickel (Ni), titanium (Ti), chromium (Cr), or an alloy thereof. However, the present disclosure is not limited thereto.

The first drain electrode DE1 is electrically connected to the high-potential power line VDD. For example, the first drain electrodes DE1 of the red subpixel SPR and the white subpixel SPW may be electrically connected to the high-potential power line VDD at the left side of the red subpixel SPR. The first drain electrodes DE1 of the blue subpixel SPB and the green subpixel SPG may be electrically connected to the high-potential power line VDD at the right side of the green subpixel SPG.

In this case, to electrically connect the first drain electrode DE1 to the high-potential power line VDD, an auxiliary high-potential power line VDDa may be further disposed. The auxiliary high-potential power line VDDa has one end electrically connected to the high-potential power line VDD, and the other end electrically connected to the first drain electrode DE1 of each of the plurality of subpixels SP. For example, in a case in which the auxiliary high-potential power line VDDa is disposed on the same layer and made of the same material as the first drain electrode DE1, one end of the auxiliary high-potential power line VDDa may be electrically connected to the high-potential power line VDD through a contact hole formed in the gate insulation layer 123 and the buffer layer 122, and the other end of the auxiliary high-potential power line VDDa may extend to the first drain electrode DE1 and be integrated with the first drain electrode DE1.

In this case, the first drain electrode DE1 of the red subpixel SPR and the first drain electrode DE1 of the white subpixel SPW, which are electrically connected to the same high-potential power line VDD, may be connected to the same auxiliary high-potential power line VDDa. The first drain electrode DE1 of the blue subpixel SPB and the first drain electrode DE1 of the green subpixel SPG may also be connected to the same auxiliary high-potential power line VDDa. However, the first drain electrode DE1 and the high-potential power line VDD may be electrically connected by means of other methods. However, the present disclosure is not limited thereto.

The first source electrode SE1 may be electrically connected to the light-blocking layer LS through a contact hole formed in the gate insulation layer 123 and the buffer layer 122. In addition, a part of the first active layer ACT1 connected to the first source electrode SE1 may be electrically connected to the light-blocking layer LS through the contact hole formed in the buffer layer 122. If the light-blocking layer LS floats, the threshold voltage of the first transistor TR1 is changed, which may affect the operation of the display device 100. Therefore, the light-blocking layer LS may be electrically connected to the first source electrode SE1, such that the voltage may be applied to the light-blocking layer LS, and the operation of the first transistor TR1 is not affected. In the present specification, the configuration has been described in which both the first active layer ACT1 and the first source electrode SE1 are in contact with the light-blocking layer LS. However, only one of the first source electrode SE1 and the first active layer ACT1 may be in direct contact with the light-blocking layer LS. The present disclosure is not limited thereto.

Meanwhile, FIG. 4 illustrates that the gate insulation layer 123 is formed on the entire surface of the first substrate 110. However, the gate insulation layer 123 may be patterned to overlap only the first gate electrode GE1, the first source electrode SE1, and the first drain electrode DE1. However, the present disclosure is not limited thereto.

The second transistor TR2 includes the second active layer ACT2, a second gate electrode GE2, a second source electrode SE2, and a second drain electrode DE2.

The second active layer ACT2 is disposed on the buffer layer 122. The second active layer ACT2 may be made of a semiconductor material such as an oxide semiconductor, amorphous silicon, or polysilicon, but the present disclosure is not limited thereto. For example, in the case in which the second active layer ACT2 is made of an oxide semiconductor, the second active layer ACT2 may include a channel area, a source area, and a drain area. The source area and the drain area may be areas having conductivity. However, the present disclosure is not limited thereto.

The second source electrode SE2 is disposed on the buffer layer 122. The second source electrode SE2 may be integrated with and electrically connected to the second active layer ACT2. For example, the second source electrode SE2 may be formed by forming a semiconductor material on the buffer layer 122 and making a part of the semiconductor material conductive. Therefore, a portion of the semiconductor material, which does not become conductive, may be the second active layer ACT2. A portion of the semiconductor material, which becomes conductive, may be the second source electrode SE2. However, the second active layer ACT2 and the second source electrode SE2 may be separately formed. However, the present disclosure is not limited thereto.

The second source electrode SE2 is electrically connected to the first gate electrode GE1 of the first transistor TR1. The first gate electrode GE1 may be electrically connected to the second source electrode SE2 through a contact hole formed in the gate insulation layer 123. Therefore, the first transistor TR1 may be turned on or off in response to a signal from the second transistor TR2.

The gate insulation layer 123 is disposed on the second active layer ACT2 and the second source electrode SE2. The second drain electrode DE2 and the second gate electrode GE2 are disposed on the gate insulation layer 123.

The second gate electrode GE2 is disposed on the gate insulation layer 123 so as to overlap the second active layer ACT2. The second gate electrode GE2 may be electrically connected to the gate line GL. The second transistor TR2 may be turned on or off on the basis of the gate voltage transmitted to the second gate electrode GE2. The second gate electrode GE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, the second gate electrode GE2 may extend from the gate line GL. That is, the second gate electrode GE2 may be integrated with the gate line GL. The second gate electrode GE2 and the gate line GL may be made of the same electrically conductive material. For example, the gate line GL may be made of copper (Cu), aluminum (Al), molybdenum (Mo), nickel (Ni), titanium (Ti), chromium (Cr), or an alloy thereof. However, the present disclosure is not limited thereto.

The gate line GL is a line for transmitting the gate voltages to the plurality of subpixels SP. The gate line GL may extend in the row direction while traversing a circuit area of the plurality of subpixels SP. The gate line GL may extend in the row direction and intersect the plurality of high-potential power lines VDD, the plurality of data lines DL, and the plurality of reference lines RL that extend in the column direction.

The second drain electrode DE2 is disposed on the gate insulation layer 123. The second drain electrode DE2 may be electrically connected to the second active layer ACT2 through a contact hole formed in the gate insulation layer 123. The second drain electrode DE2 may be electrically connected to one of the plurality of data lines DL through the contact hole formed in the gate insulation layer 123 and the buffer layer 122. For example, the second drain electrode DE2 of the red subpixel SPR may be electrically connected to the first data line DL1. The second drain electrode DE2 of the white subpixel SPW may be electrically connected to the second data line DL2. For example, the second drain electrode DE2 of the blue subpixel SPB may be electrically connected to the third data line DL3. The second drain electrode DE2 of the green subpixel SPG may be electrically connected to the fourth data line DL4. The second drain electrode DE2 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The third transistor TR3 includes the third active layer ACT3, a third gate electrode GE3, a third source electrode SE3, and a third drain electrode DE3.

The third active layer ACT3 is disposed on the buffer layer 122. The third active layer ACT3 may be made of a semiconductor material such as an oxide semiconductor, amorphous silicon, or polysilicon, but the present disclosure is not limited thereto. For example, in the case in which the third active layer ACT3 is made of an oxide semiconductor, the third active layer ACT3 may include a channel area, a source area, and a drain area. The source area and the drain area may be areas having conductivity. However, the present disclosure is not limited thereto.

The gate insulation layer 123 is disposed on the third active layer ACT3. The third gate electrode GE3, the third source electrode SE3, and the third drain electrode DE3 are disposed on the gate insulation layer 123.

The third gate electrode GE3 is disposed on the gate insulation layer 123 so as to overlap the third active layer ACT3. The third gate electrode GE3 may be electrically connected to the sensing line SL. The third transistor TR3 may be turned on or off on the basis of the sensing voltage transmitted to the third transistor TR3. The third gate electrode GE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, the third gate electrode GE3 may extend from the sensing line SL. That is, the third gate electrode GE3 may be integrated with the sensing line SL. The third gate electrode GE3 and the sensing line SL may be made of the same electrically conductive material. For example, the sensing line SL may be made of copper (Cu), aluminum (Al), molybdenum (Mo), nickel (Ni), titanium (Ti), chromium (Cr), or an alloy thereof. However, the present disclosure is not limited thereto.

The sensing line SL is a line that transmits the sensing voltages to the plurality of subpixels SP and extends in the row direction between the plurality of subpixels SP. For example, the sensing line SL may extend in the row direction at a boundary between the plurality of subpixels SP and intersect the plurality of high-potential power lines VDD, the plurality of data lines DL, and the plurality of reference lines RL that extend in the column direction.

The third source electrode SE3 may be electrically connected to the third active layer ACT3 through a contact hole formed in the gate insulation layer 123. The third source electrode SE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, a part of the third active layer ACT3, which is in contact with the third source electrode SE3, may be electrically connected to the light-blocking layer LS through a contact hole formed in the buffer layer 122. That is, the third source electrode SE3 may be electrically connected to the light-blocking layer LS with the third active layer ACT3 interposed therebetween. Therefore, the third source electrode SE3 and the first source electrode SE1 may be electrically connected to each other through the light-blocking layer LS.

The third drain electrode DE3 may be electrically connected to the third active layer ACT3 through a contact hole formed in the gate insulation layer 123. The third drain electrode DE3 may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The third drain electrode DE3 may be electrically connected to the reference line RL. For example, the third drain electrodes DE3 of the red subpixel SPR, the white subpixel SPW, the blue subpixel SPB, and the green subpixel SPG, which constitute the single pixel, may be electrically connected to the same reference line RL. That is, the plurality of subpixels SP, which constitute a single pixel, may share the single reference line RL.

In this case, an auxiliary reference line RLa may be disposed to transmit signals to the plurality of subpixels SP disposed side by side in the row direction through the reference line RL extending in the column direction. The auxiliary reference line RLa may extend in the row direction and electrically connect the reference line RL to the third drain electrode DE3 of each of the plurality of subpixels SP. One end of the auxiliary reference line RLa may be electrically connected to the reference line RL through a contact hole formed in the buffer layer 122 and the gate insulation layer 123. Further, the other end of the auxiliary reference line RLa may be electrically connected to the third drain electrode DE3 of each of the plurality of subpixels SP. In this case, the auxiliary reference line RLa may be integrated with the third drain electrode DE3 of each of the plurality of subpixels SP. The reference voltage may be transmitted from the reference line RL to the third drain electrode DE3 through the auxiliary reference line RLa. However, the auxiliary reference line RLa may be formed separately from the third drain electrode DE3. However, the present disclosure is not limited thereto.

The storage capacitor SC is disposed in the circuit area CA of the plurality of subpixels SP. The storage capacitor SC may store a voltage between the first gate electrode GE1 and the first source electrode SE1 of the first transistor TR1 so that the light-emitting element OLED may continuously maintain the same state during a single frame. The storage capacitor SC may include a first capacitor electrode SC1 and a second capacitor electrode SC2.

The first capacitor electrode SC1 is disposed between the insulation layer 121 and the buffer layer 122 in each of the plurality of subpixels SP. The first capacitor electrode SC1 may be disposed to be closest to the first substrate 110 among the conductive constituent elements disposed on the first substrate 110. The first capacitor electrode SC1 may be integrated with the light-blocking layer LS. The first capacitor electrode SC1 may be electrically connected to the first source electrode SE1 through the light-blocking layer LS.

The buffer layer 122 is disposed on the first capacitor electrode SC1. The second capacitor electrode SC2 is disposed on the buffer layer 122. The second capacitor electrode SC2 may be disposed to overlap the first capacitor electrode SC1. The second capacitor electrode SC2 may be integrated with the second source electrode SE2 and electrically connected to the second source electrode SE2 or the first gate electrode GE1. For example, the second source electrode SE2 and the second capacitor electrode SC2 may be formed by forming a semiconductor material on the buffer layer 122 and making a part of the semiconductor material conductive. Therefore, a portion of the semiconductor material, which does not become conductive, may serve as the second active layer ACT2. A portion of the semiconductor material, which becomes conductive, may serve as the second source electrode SE2 or the second capacitor electrode SC2. Further, as described above, the first gate electrode GE1 is electrically connected to the second source electrode SE2 through the contact hole formed in the gate insulation layer 123. Therefore, the second capacitor electrode SC2 may be integrated with the second source electrode SE2 and electrically connected to the second source electrode SE2 and the first gate electrode GE1.

In summary, the first capacitor electrode SC1 of the storage capacitor SC may be integrated with the light-blocking layer LS and electrically connected to the light-blocking layer LS, the first source electrode SE1, and the third source electrode SE3. Further, the second capacitor electrode SC2 may be integrated with the second source electrode SE2 or the second active layer ACT2 and electrically connected to the second source electrode SE2 and the first gate electrode GE1. Therefore, the first capacitor electrode SC1 and the second capacitor electrode SC2, which overlap each other with the buffer layer 122 interposed therebetween, may maintain the light-emitting element OLED in the constant state by constantly maintaining the voltages of the first gate electrode GE1 and the first source electrode SE1 of the first transistor TR1 while the light-emitting element OLED emits light.

The passivation layer 124 is disposed on the first transistor TR1, the second transistor TR2, the third transistor TR3, and the storage capacitor SC. The passivation layer 124 is an insulation layer for protecting the components disposed below the passivation layer 124. For example, the passivation layer 124 may be configured as a single layer or multilayer made of silicon oxide (SiOx) or silicon nitride (SiNx). However, the present disclosure is not limited thereto. In addition, the passivation layer 124 may be omitted in accordance with the example embodiments.

The plurality of color filters CF is disposed in the light-emitting area EA of each of the plurality of subpixels SP and provided on the passivation layer 124. As described above, the display device 100 according to the example embodiment of the present disclosure is the bottom-emission type display device that allows the light emitted from the light-emitting element OLED to propagate to the lower sides of the light-emitting element OLED and the first substrate 110. Therefore, the plurality of color filters CF may be disposed below the light-emitting element OLED. The light emitted from the light-emitting element OLED may be implemented in the form of light beams with various colors by passing through the plurality of color filters CF.

The plurality of color filters CF includes the red color filter CFR, a blue color filter CFB, and the green color filter CFG. The red color filter CFR may be disposed in the light-emitting area of the red subpixel SPR among the plurality of subpixels SP. The blue color filter CFB may be disposed in the light-emitting area of the blue subpixel SPB. The green color filter CFG may be disposed in the light-emitting area of the green subpixel SPG.

The overcoating layer 130 is disposed on the passivation layer 124 and the plurality of color filters CF. The overcoating layer 130 is an insulation layer for flattening an upper portion of the first substrate 110 on which the first transistor TR1, the second transistor TR2, the third transistor TR3, the storage capacitor SC, the plurality of high-potential power lines VDD, the plurality of data lines DL, the plurality of reference lines RL, the plurality of gate lines GL, and the plurality of sensing lines SL are disposed. The overcoating layer 130 may be configured as a single layer or multilayer made of an organic material, for example, polyimide or photo acrylic. However, the present disclosure is not limited thereto.

The light-emitting element OLED is disposed in the light-emitting area of each of the plurality of subpixels SP. The light-emitting element OLED is disposed on the overcoating layer 130 of each of the plurality of subpixels SP. The light-emitting element OLED includes the anode AN, a light-emitting layer EL, and a cathode CA.

The anode AN is disposed on the overcoating layer 130 in the light-emitting area EA. Because the anode AN supplies holes to the light-emitting layer EL, the anode AN may be made of an electrically conductive material having a high work function. For example, the anode AN may be made of a transparent electrically conductive material such as indium tin oxide (ITO) or indium zinc oxide (IZO), but the present disclosure is not limited thereto.

Meanwhile, the anode AN may extend toward the circuit area CA. A part of the anode AN may extend from the light-emitting area EA toward the first source electrode SE1 of the circuit area CA and be electrically connected to the first source electrode SE1 through the contact hole formed in the overcoating layer 130 and the passivation layer 124. Therefore, the anode AN of the light-emitting element OLED may extend to the circuit area CA and be electrically connected to the first source electrode SE1 of the first transistor TR1 or the second capacitor electrode SC2 of the storage capacitor SC.

The light-emitting layer EL is disposed on the anode AN in the light-emitting area EA and the circuit area CA. The light-emitting layer EL may be configured as a single layer over the plurality of subpixels SP. That is, the light-emitting layers EL of the plurality of subpixels SP may be connected to and integrated with one another. The light-emitting layer EL may be configured as a single light-emitting layer. The light-emitting layer EL may have a structure in which a plurality of light-emitting layers configured to emit light beams with different colors is stacked. The light-emitting layer EL may further include organic layers such as a hole injection layer, a hole transport layer, an electron transport layer, and an electron injection layer.

The cathode CA is disposed on the light-emitting layer EL in the light-emitting area EA and the circuit area CA. Because the cathode CA supplies electrons to the light-emitting layer EL, the cathode CA may be made of an electrically conductive material having a low work function. The cathode CA may be configured as a single layer over the plurality of subpixels SP. That is, the cathodes CA of the plurality of subpixels SP may be connected to and integrated with one another. For example, the cathode CA may be made of an electrically transparent conductive material such as indium tin oxide (ITO) or indium zinc oxide (IZO) or made of an alloy of ytterbium (Yb). The cathode CA may further include a metal doping layer, but the present specification is not limited thereto. Meanwhile, although not illustrated in FIGS. 3 and 4, the cathode CA of the light-emitting element OLED may be electrically connected to the low-potential power line VSS and receive the low-potential power voltage.

The bank BNK is disposed between the anode AN and the light-emitting layer EL. The bank BNK is disposed to overlap the display area AA and cover an edge of the anode AN. The bank BNK may be disposed at a boundary between the adjacent subpixels SP and reduce mixing of colors of the light beams emitted from the light-emitting element OLED of each of the plurality of subpixels SP. The bank BNK may be made of an insulating material. For example, the bank BNK may be made of polyimide-based resin, acryl-based resin, or benzocyclobutene (BCB)-based resin. However, the present disclosure is not limited thereto.

The adhesive layer 140 is disposed on the cathode CA. The adhesive layer 140 may bond the first substrate 110 and the second substrate 150. The adhesive layer 140 may be made of resin, for example, any one of epoxy, phenol, amino, unsaturated polyester, polyimide, silicone, acrylic, vinyl, and olefin. The adhesive layer 140 may be bonded by high-energy curing using heat, ultraviolet rays, and laser beams. The adhesive layer 140 may be bonded by a method of applying physical pressure by using a pressure sensitive adhesive (PSA). The adhesive layer 140 may include a plurality of layers. For example, the adhesive layer 140 may include a layer containing epoxy and poly olefin, and a moisture-absorbing filter layer. In this case, the moisture-absorbing filter layer may be a moisture adsorbent. The adhesive layer 140 may have a larger area than the display area AA and be disposed to cover the entire display area AA so that the adhesive layer 140 covers the entire light-emitting element OLED in the display area AA in order to obtain a sealing effect.

The second substrate 150 is disposed on the adhesive layer 140. The second substrate 150 may be a thin-film metal substrate (face seal metal (FSM)) made of an opaque material. More specifically, the second substrate 150 may be disposed to cover the entire display area AA in order to protect the plurality of subpixels SP disposed on the first substrate 110 from external impact and scratches. For example, the metallic material, which constitutes the second substrate 150, may be a material having a high modulus of about 200 to 900 MPa. The second substrate 150 may be made of an alloy of aluminum (Al), nickel (Ni), chromium (Cr), iron (Fe), and nickel that are easily machined in the form of a foil or thin-film and have high corrosion resistance.

The second substrate 150 may have a size smaller than a size of the first substrate 110. More specifically, the second substrate 150 exposes the flexible films 170 to the outside, and the flexible films 170 are electrically connected to one end of the first substrate 110. In this case, an end of the second substrate 150 and an end of a flexible film 170 may be spaced apart from each other at a predetermined distance.

A film member is disposed on a lower portion of the first substrate 110. The film member may include at least one of the polarizing plate 160 and a barrier film. For example, the polarizing plate 160 is disposed below the first substrate 110. The polarizing plate 160 may selectively transmit light and reduce the reflection of external light entering the first substrate 110. Specifically, the display device 100 has various metallic materials formed on the first substrate 110 and applied to a semiconductor element, a line, and a light-emitting element. Therefore, the external light entering the first substrate 110 may be reflected by the metallic material. The reflection of external light may decrease visibility of the display device 100. In this case, the polarizing plate 160 for suppressing the reflection of external light may be disposed below the first substrate 110, thereby improving outdoor visibility of the display device 100. The polarizing plate 160 may be attached to the first substrate 110 by an adhesive. However, the polarizing plate 160 may be omitted in accordance with the implementation of the display device 100.

Meanwhile, a barrier film may be disposed on a lower portion of the first substrate 110 together with the polarizing plate 160. Alternatively, the barrier film may be disposed in a state in which the polarizing plate 160 is omitted. The barrier film may minimize the penetration of moisture and oxygen present outside the first substrate 110 into the first substrate 110, thereby protecting the light-emitting element OLED. However, the barrier film may be omitted in accordance with the implementation of the display device 100. However, the present disclosure is not limited thereto.

With reference to FIG. 1, the non-display area NA of the first substrate 110 is an area in which no image is displayed. Various lines, drive ICs, and the like for operating the subpixels SP disposed in the display area AA are disposed in the non-display area NA. For example, various drive ICs such as a gate driver IC and a data driver IC may be disposed in the non-display area NA.

The plurality of flexible films 170 is disposed at one end of the non-display area of the first substrate 110. Each of the plurality of flexible films 170 is a film having various types of components disposed on a base film having flexibility in order to supply signals to the plurality of subpixels SP in the display area AA. The plurality of flexible films 170 may each be disposed in the non-display area NA of the first substrate 110 and supply data voltage or the like to the plurality of subpixels in the display area AA. Meanwhile, FIG. 1 illustrates four flexible films 170. However, the number of flexible films 170 may be variously changed in accordance with design. However, the present disclosure is not limited thereto.

The drive ICs such as gate driver ICs and data driver ICs may be disposed on the plurality of flexible films 170. The drive IC is a component configured to process data for displaying the image and process a driving signal for processing the data. The drive IC may be disposed in ways such as a chip-on-glass (COG) method, a chip-on-film (COF) method, and a tape carrier package (TCP) method depending on how the drive IC is mounted. In the present specification, for the convenience of description, a configuration has been described in which the drive ICs are mounted on the plurality of flexible films 170 by the chip-on-film method. However, the present disclosure is not limited thereto.

The printed circuit boards 180 are connected to the plurality of flexible films 170. The printed circuit board 180 is a component for supplying a signal to a drive IC. Various types of components for supplying the drive IC with various driving signals such as driving signals, data voltages, and the like may be disposed on the printed circuit board 180. Meanwhile, FIG. 1 illustrates two printed circuit boards 180. However, the number of printed circuit boards 180 may be variously changed in accordance with design. The present disclosure is not limited thereto.

The first substrate 110 of the display device 100 according to the example embodiment of the present disclosure is made of any one of a transparent conducting oxide and an oxide semiconductor. Therefore, the display device 100 may decrease in thickness. In the related art, a plastic substrate is mainly used for a substrate of a display device. However, because the plastic substrate is formed by applying and curing a substrate material at a high temperature, there is a problem in that a large amount of time is required, and it is difficult to reduce a thickness to a predetermined level or less. In contrast, the transparent conducting oxide and the oxide semiconductor may allow the display device to have a very small thickness through a deposition process such as sputtering. Therefore, in the display device 100 according to the example embodiment of the present disclosure, the first substrate 110 for supporting several components of the display device 100 is made of transparent conducting oxide or oxide semiconductor. Therefore, it is possible to reduce a thickness of the display device 100 and implement slim design.

In the display device 100 according to the example embodiment of the present disclosure, the first substrate 110 is made of the transparent conducting oxide or oxide semiconductor, such that it is possible to improve the flexibility of the display device 100 or reduce stress caused by the deformation of the display device 100. Specifically, when the first substrate 110 is made of the transparent conducting oxide or oxide semiconductor, the first substrate 110 may be formed to be a very thin film. In this case, the first substrate 110 may be referred to as a transparent thin-film layer. Therefore, the display device 100 including the first substrate 110 may have high flexibility. Therefore, the display device 100 may be easily curved or rolled up. Therefore, in the display device 100 according to the example embodiment of the present disclosure, the first substrate 110 is made of the transparent conducting oxide or the oxide semiconductor, such that it is possible to improve flexibility of the display device 100 and reduce stress caused by the deformation of the display device 100. Therefore, it is possible to minimize cracks formed in the display device 100.

In addition, in the display device 100 according to the example embodiment of the present disclosure, the first substrate 110 is made of the transparent conducting oxide or the oxide semiconductor. Therefore, it is possible to minimize the penetration of outside moisture or oxygen into the display device 100 through the first substrate 110. When the first substrate 110 is made of the transparent conducting oxide or the oxide semiconductor, the first substrate 110 may be formed in a vacuum environment, such that the likelihood of the occurrence of particles is remarkably low. In addition, sizes of the particles are very small even though the particles occur. Therefore, it is possible to minimize the penetration of moisture and oxygen into the display device 100. Therefore, in the display device 100 according to the example embodiment of the present disclosure, the substrate is made of the transparent conducting oxide or oxide semiconductor that decreases the likelihood of the occurrence of particles and is excellent in moisture transmission performance. Therefore, it is possible to improve reliability of the display device 100 and the light-emitting element OLED including the organic layer.

Meanwhile, in a general display device, a plurality of flexible films is electrically connected to the first substrate by a bonding member that has conductivity and is disposed adjacent to the end of the first substrate. As described above, when the bonding member is disposed adjacent to the end (e.g., edge(s)) of the first substrate at the time of bonding the plurality of flexible films to the first substrate, the bonding member is expanded and spread by the plurality of flexible films. For this reason, the bonding member may flow to a side surface of the first substrate and a side surface of a temporary substrate at the lower side. As described above, in case that the bonding member flows to the side surface of the first substrate and the side surface of the temporary substrate, the laser lift-off (LLO) process may not be easily performed. In this case, because the first substrate is made of transparent conducting oxide or oxide semiconductor and has a small thickness, the LLO process means a process of disposing the components of the display device in a state in which the temporary substrate is present at the lower side, and separating the first substrate and the temporary substrate below the first substrate by using a laser during the process of manufacturing the display device.

To solve the problem, the bonding member is spaced apart from and positioned inward of the end of the first substrate by a predetermined distance during the process of bonding the plurality of flexible films to the first substrate. However, even in this case, the bonding member may flow in the direction of the display area and contact the second substrate. When the bonding member and the second substrate are in contact with each other as described above, the bonding member and the second substrate are electrically connected, which may cause a problem of a leakage current.

In particular, when a leakage current occurs on the data line of the flexible display device, a difference Vgs between a gate voltage and a source voltage of the driving transistor decreases, and a line defect (LD) occurs in a vertical direction, which causes a problem in which a dark line is formed in the vertical direction.

In addition, when a leakage current occurs on the high-potential power line of the flexible display device, a voltage of the anode decreases. For this reason, when a voltage drop occurs for each of the flexible films, there is a problem in that there occurs a difference in brightness between the subpixels respectively connected to the flexible films.

In addition, when a leakage current occurs on a line connected to a gate drive part, clock signals cannot be sequentially outputted from respective stages that constitute the gate drive part. For this reason, there is a problem in that the horizontal subpixels connected to the corresponding stage, which cannot output the clock signal, are not turned on, which causes a horizontal line defect.

Therefore, the display device 100 according to the example embodiment of the present disclosure may include a blocking film that inhibits the bonding member and the second substrate 150 from being electrically connected.

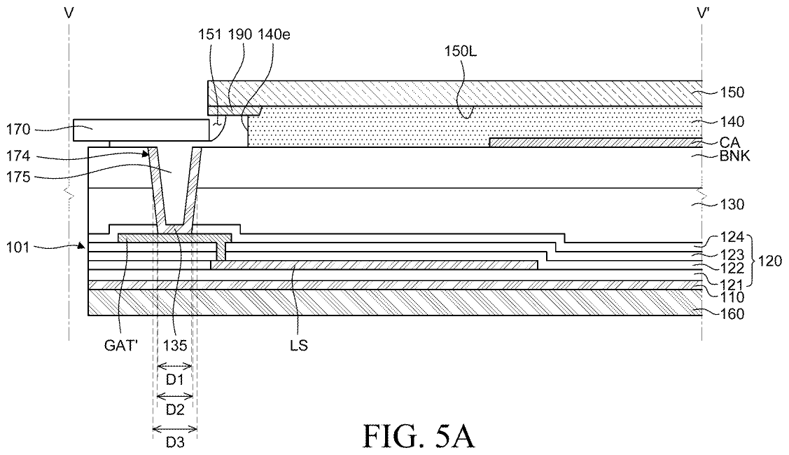

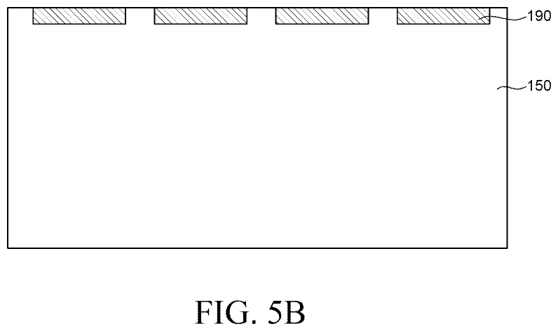

FIG. 5A is a cross-sectional view taken along line V-V′ in FIG. 1. FIG. 5B is a top plan view illustrating the blocking film and the second substrate of the display device according to the example embodiment of the present disclosure.

First, with reference to FIG. 5A, in the non-display area NA of the display device 100 according to the example embodiment of the present disclosure, an inorganic insulation layer 120, the overcoating layer 130, the bank BNK, the cathode CA of the light-emitting element OLED are disposed on the first substrate 110 and extend from the display area AA. In the description herein, the first substrate 110 and the stack of structures/layers positioned thereon to form the OLED are referred to together as a first body 101 for descriptive purposes only. The adhesive layer 140, and the second substrate 150 are disposed on the first body 101 including the first substrate 110, and extend from the display area AA. In a plan view, the inorganic insulation layer 120, the overcoating layer 130, the bank BNK, the cathode CA of the light-emitting element OLED, the adhesive layer 140, and the second substrate 150 may be located inside an area of the first substrate 110. In some implementations, the second substrate 150 extends beyond the adhesive layer 140 such that an undercut region 151 is formed among the second substrate 150, the adhesive layer 140, and the first body 101, in the illustrative example of FIG. 5A, the bank BNK of the first body 101. In the description herein, with respect to any layers formed on the first body 101, e.g., the adhesive layer 140 and the second substrate 150, either the first body 101 or the first substrate 110 may be used to describe the relative position/structure relationships thereof. For example, when first substrate 110 is referred to with respect to the second substrate 150, the first substrate 110 may also refer to structures/layers formed on the first substrate 110, e.g., the bank BNK, the overcoating layer 130.

The inorganic insulation layer 120 may be disposed to extend to the end (e.g., edge) of the first substrate 110. The inorganic insulation layer 120 may be formed by sequentially stacking the insulation layer 121, the buffer layer 122, the gate insulation layer 123, and the passivation layer 124. That is, the passivation layer 124 may be an insulation layer disposed on an uppermost layer of the inorganic insulation layer 120.

The light-blocking layer LS is disposed on the insulation layer 121. The light-blocking layer LS may be adjacent to a link line by being electrically connected to an additional gate pattern GAT′, which is disposed on the gate insulation layer 123, through contact holes formed in the buffer layer 122 and the gate insulation layer 123.

The overcoating layer 130 and the bank BNK are sequentially disposed on the inorganic insulation layer 120. The overcoating layer 130 and the bank BNK may be disposed to extend to the end of the first substrate 110.

A hole or holes 174 are formed in and extending through the passivation layer 124, the overcoating layer 130, and the bank BNK at an inner position spaced apart from the end of the first substrate 110 at a predetermined distance. In this case, one end of each of the holes formed in the passivation layer 124, the overcoating layer 130, and the bank BNK may be positioned at a position spaced apart from the end of the first substrate 110 at a predetermined distance. The other end of each of the holes formed in the passivation layer 124, the overcoating layer 130, and the bank BNK may correspond to the end of the second substrate 150. The holes 174, which are formed in the passivation layer 124, the overcoating layer 130, and the bank BNK as described above, are filled with a bonding member 175 for bonding the flexible film 170. The bonding member 175 may be a conductive adhesive that may be made of adhesive resin including fine conductive particles. For example, the bonding member 175 may be an anisotropic conductive film (ACF). The holes 174 each has a first width dimension D1 in the passivation layer 124, a second width dimension D2 in the overcoating layer 130, and a third width dimension D3 in the bank BNK. The first width dimension D1 and the second width dimension D2 are each different from, e.g., smaller than, the third width dimension D3. The first dimension D1 of the hole 174 is smaller than each of the second dimension D2 and the third dimension D3.

The flexible film 170 may be disposed on the bonding member 175. At the time of bonding the flexible film 170, the bonding member 175 may overflow in the direction of the display area. Therefore, as illustrated in FIG. 5A, the bonding member 175 may overflow in the direction of the second substrate 150, and may fill partially the undercut region 151. A blocking film 190 may suppress the contact between the bonding member 175 and the second substrate 150. The blocking film 190 is form on the lower surface 150L of the second substrate 150 that faces the first body 101 and adjacent to the undercut region 151. In the display device 100 according to the example embodiment of the present disclosure, the holes are formed in the passivation layer 124, the overcoating layer 130, and the bank BNK, the formed holes are filled with the bonding member 175, and the bonding member 175 overflows toward the second substrate 150 and the blocking film 190, such that the LLO process may be easily performed.

A pad part 135 may be disposed along a part of an inner surface of the hole. More specifically, as the hole is formed in the passivation layer 124, a top surface of the additional gate pattern GAT′ may be exposed. The pad part 135 may be disposed along an inner side surface of the hole so as to correspond to the top surface of the additional gate pattern GAT′ and the height of the overcoating layer 130. The pad part 135 may be made of a transparent conducting oxide material, for example, a material such as indium tin oxide (ITO), indium zinc oxide (IZO), or indium tin zinc oxide (ITZO). The pad part 135 may be formed at the same time when the anode AN of the display area AA is formed.

With reference to FIGS. 5A and 5B, a plurality of blocking films 190 is disposed on a lower surface of the second substrate 150. The plurality of blocking films 190 may be disposed to correspond to a position of the bonding member 175. In this case, the plurality of blocking films 190 may correspond in number to the flexible films 170.

The blocking films 190 may be disposed to overlap the adhesive layer 140 in a cross-sectional view. That is, as illustrated in FIG. 5A, the blocking films 190 may be disposed to overlap and in contact with an end 140e of the adhesive layer 140.

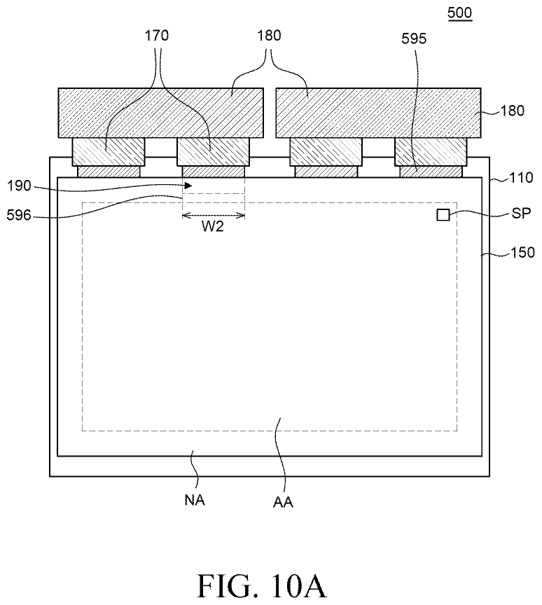

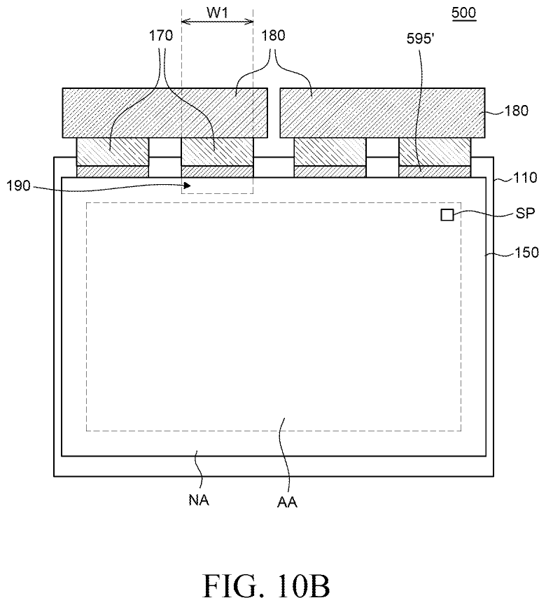

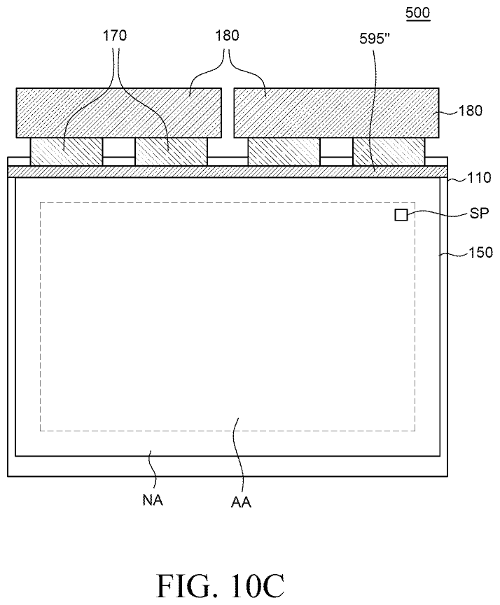

The blocking films 190 may be disposed to have a width W1 corresponding to a boundary of the flexible films 170 in a plan view (FIG. 10B). However, the present disclosure is not limited thereto. The blocking films 190 may be disposed to have a width W2 corresponding to a boundary of a routing line 596 in a plan view (FIG. 10A).

The blocking films 190 of the display device 100 according to the example embodiment of the present disclosure are disposed to suppress the contact with the second substrate 150 caused by an inward overflow of the bonding member 175. Therefore, the blocking films 190 may be made of an insulating material, more specifically any one of an inorganic insulating material and an organic insulating material. The blocking films 190 may be disposed on the lower surface of the second substrate 150 so as to overlap the adhesive layer 140, thereby improving insulation properties between the second substrate 150 and the bonding member 175.

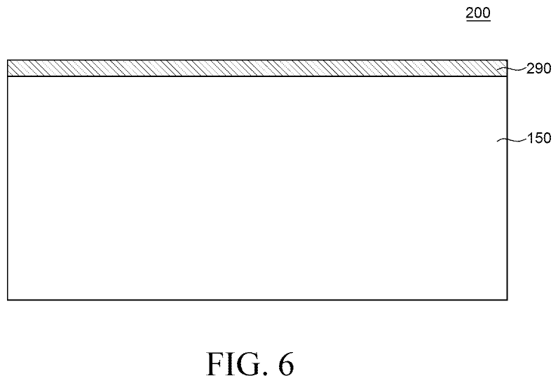

FIG. 6 is a top plan view illustrating a blocking film and a second substrate of a display device according to another example embodiment of the present disclosure. A display device 200 in FIG. 6 is substantially identical in configuration to the display device 100 in FIGS. 1 to 5B, except for a blocking film 290. Therefore, repeated descriptions of the identical components will be omitted.

With reference to FIG. 6, the blocking film 290 is disposed on the lower surface of the second substrate 150. The number of blocking films 290 may be 1. In addition, in a plan view, the blocking film 290 may be disposed along one end of the second substrate 150 corresponding to one end of the first substrate 110 connected to the flexible film 170. That is, the single blocking film 290 may be disposed along one end of the second substrate 150.

The blocking film 290 of the display device 200 according to another example embodiment of the present disclosure is disposed to suppress the contact with the second substrate 150 caused by an inward overflow of the bonding member 175. In this case, the blocking film 290 may be configured as a single layer and disposed along one end of the second substrate 150. Therefore, in the display device 200 according to another example embodiment of the present disclosure, the blocking film 290 may be disposed in both the area corresponding to the plurality of flexible films 170 and the area between the plurality of flexible films 170 so as to overlap the bonding member 175, thereby improving insulation properties between the second substrate 150 and the bonding member 175.

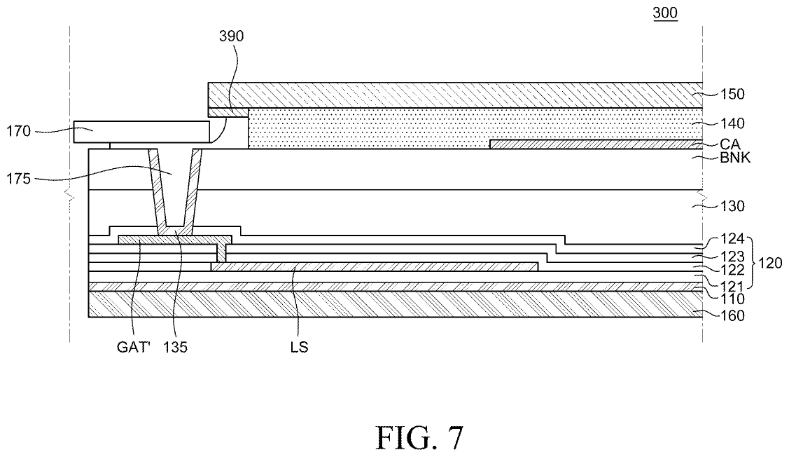

FIG. 7 is a cross-sectional view of a display device according to still another example embodiment of the present disclosure. A display device 300 in FIG. 7 is substantially identical in configuration to the display device 100 in FIGS. 1 to 5B, except for a blocking film 390. Therefore, repeated descriptions of the identical components will be omitted.

With reference to FIG. 7, a plurality of blocking films 390 is disposed on the lower surface of the second substrate 150. The plurality of blocking films 390 may be disposed to correspond to a position of the bonding member 175. In this case, the plurality of blocking films 390 may correspond in number to the flexible films 170.

The blocking films 390 may be disposed to be in contact with the end of the adhesive layer 140 in a cross-sectional view. That is, a plurality of blocking films 390 of the display device 300 according to another example embodiment of the present disclosure may each have a smaller width than the plurality of blocking films 190 illustrated in FIGS. 1 to 5B.

The blocking films 390 of the display device 300 according to still another example embodiment of the present disclosure is disposed to suppress the contact with the second substrate 150 caused by the inward overflow of the bonding member 175. In this case, the blocking films 390 may be disposed to be in contact with the end of the adhesive layer 140. When the bonding member 175 overflows, the adhesive layer 140 inhibits the bonding member 175 from moving to a central portion of the display device 300, such that the blocking films 390 may be disposed to be in contact with the end of the adhesive layer 140 while having a minimum area without overlapping the adhesive layer 140. Therefore, in the display device 300 according to still another example embodiment of the present disclosure, the blocking films 390 may improve insulation properties between the second substrate 150 and the bonding member 175 while having a minimum area.

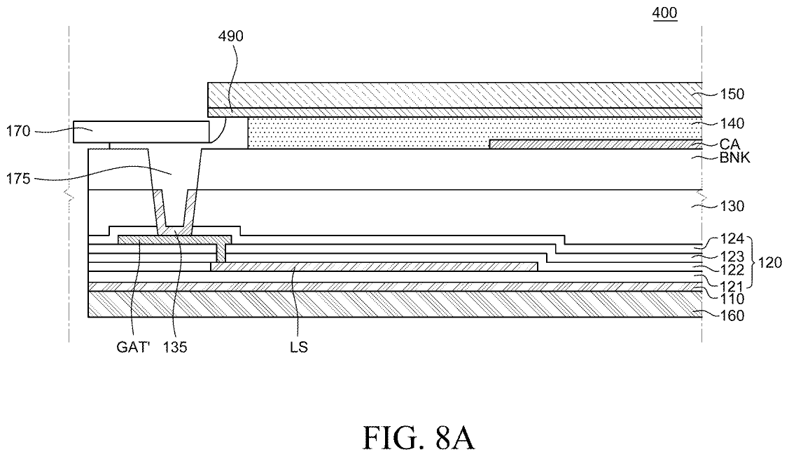

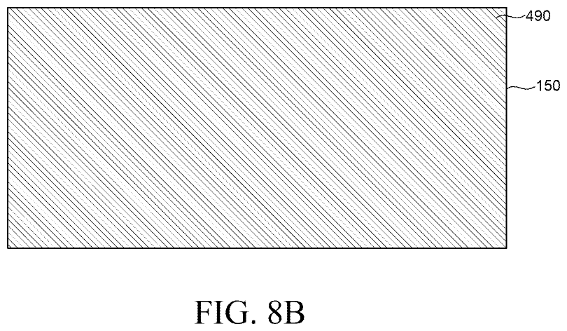

FIG. 8A is a cross-sectional view of a display device according to yet another example embodiment of the present disclosure. FIG. 8B is a top plan view illustrating a blocking film and a second substrate of the display device according to yet another example embodiment of the present disclosure. A display device 400 in FIGS. 8A and 8B is substantially identical in configuration to the display device 100 in FIGS. 1 to 5B, except for a blocking film 490. Therefore, repeated descriptions of the identical components will be omitted.

With reference to FIG. 8A and FIG. 8B, the blocking film 490 is disposed on the lower surface of the second substrate 150. Specifically, the blocking film 490 may be made of an insulating material and disposed in an entire area of the lower surface of the second substrate 150. That is, an area of the lower surface of the second substrate 150 may be equal to an area of a top surface of the blocking film 490. The entire lower surface of the second substrate 150 and the entire top surface of the blocking film 490 may overlap each other while being in contact with each other.

The blocking film 490 of the display device 400 according to yet another example embodiment of the present disclosure is disposed to suppress the contact with the second substrate 150 caused by the inward overflow of the bonding member 175. In this case, the blocking film 490 may be disposed to be in contact with the entire lower surface of the second substrate 150. Therefore, in the display device 400 according to yet another example embodiment of the present disclosure, the blocking film 490 may cover the entire area of the second substrate 150, thereby further improving insulation properties between the second substrate 150 and the bonding member 175. In addition, in the display device 400 according to yet another example embodiment of the present disclosure, a separate patterning process is not required to form the blocking film 490. Therefore, it is possible to simplify the process of manufacturing the blocking film 490. In addition, in the display device 400 according to yet another example embodiment of the present disclosure, the blocking film 490 made of an insulating material may be disposed on the entire lower surface of the second substrate 150, thereby improving the sealing properties.

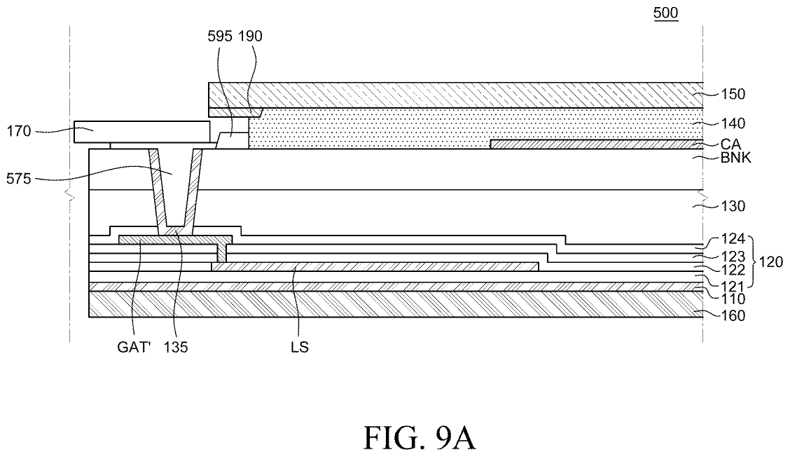

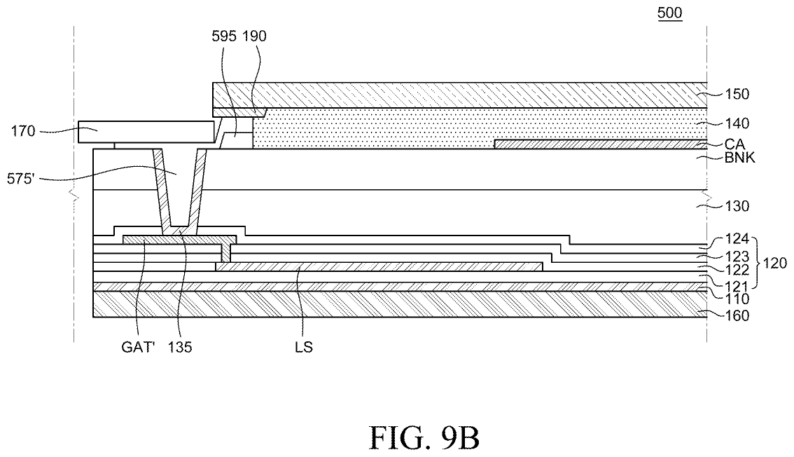

FIGS. 9A and 9B are cross-sectional views of a display device according to still yet another example embodiment of the present disclosure. A display device 500 in FIGS. 9A and 9B is substantially identical in configuration to the display device 100 in FIGS. 1 to 5B, except that an additional bank 595 is added, and bonding members 575 and 575′ are provided. Therefore, repeated descriptions of the identical components will be omitted.

With reference to FIGS. 9A and 9B, the additional bank 595 may be further disposed on the bank BNK. The additional bank 595 may be a kind of dam that suppresses overflows of the bonding members 575 and 575′.

One end of the additional bank 595 may not overlap the flexible film 170, but may be disposed to be closer to a central portion of the display device 500 than the flexible film 170 to the central portion of the display device 500. In case that one end of the additional bank 595 overlaps the flexible film 170, the overflow amount of the bonding members 575 and 575′ may increase. Therefore, one end of the additional bank 595 may be disposed so as not to overlap the flexible film 170. In addition, the other end of the additional bank 595 may be disposed to be in contact with the adhesive layer 140. However, the present disclosure is not limited thereto. The other end of the additional bank 595 may be spaced apart from the adhesive layer 140.

The additional bank 595 and the bank BNK may be provided as separate layers. That is, the additional bank 595 and the bank BNK may be independently formed by separate processes. However, the present disclosure is not limited thereto. The additional bank 595 and the bank BNK may be integrated by being simultaneously formed by the same process.

The additional bank 595 may be made of the same material as the bank BNK. For example, the additional bank 595 may be made of, but not limited to, polyimide-based resin, acryl-based resin, or benzocyclobutene (BCB)-based resin. In addition, the additional bank 595 may be made of an organic insulating material different from the material of the bank BNK in accordance with design.

With reference to FIG. 9A, the additional bank 595 may suppress the overflow of the bonding member 575. In this case, as illustrated in FIG. 9A, the overflow of the bonding member 575 is suppressed by the additional bank 595, and the bonding member 575 may be disposed to be spaced apart from the blocking film 190.

Meanwhile, with reference to FIG. 9B, the bonding member 575′ may overflow even though the additional bank 595 is used. In this case, the bonding member 575′ may be disposed to be in contact with the blocking film 190. However, the insulation between the bonding member 575′ and the second substrate 150 may be maintained by the blocking film 190.

The display device 500 according to still yet another example embodiment of the present disclosure may include the additional bank 595, thereby minimizing the overflows of the bonding members 575 and 575′. For example, as illustrated in FIG. 9A, the additional bank 595 may suppress the overflow of the bonding member 575, such that the bonding member 575 may be spaced apart from the blocking film 190 and the second substrate 150. Therefore, in the display device 500 according to still yet another example embodiment of the present disclosure, it is possible to further improve insulation properties between the second substrate 150 and the bonding member 575. In case that the bonding member 575′ overflows even though the additional bank 595 is provided as illustrated in FIG. 9B, the blocking film 190 may be disposed to maintain the insulation between the second substrate 150 and the bonding member 575′.

FIGS. 10A to 10C are top plan views illustrating several examples of arrangements of additional banks of a display device according to still yet another example embodiment of the present disclosure.

First, with reference to FIG. 10A, the additional bank 595 may be disposed to have a width corresponding to a boundary of a routing line 596 disposed in the non-display area NA in a plan view. In addition, with reference to FIG. 10B, an additional bank 595′ may be disposed to have a width corresponding to a boundary of the flexible film 170 disposed in the non-display area NA. In addition, with reference to FIG. 10C, an additional bank 595″ may be disposed along one end of the first substrate 110 connected to the flexible film 170.

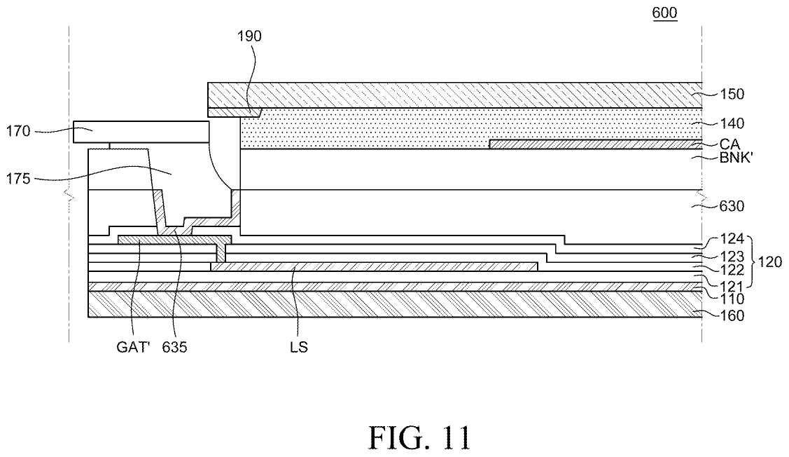

FIG. 11 is a cross-sectional view of a display device according to a further example embodiment of the present disclosure. A display device 600 in FIG. 11 is substantially identical in configuration to the display device 100 in FIGS. 1 to 5B, except for a pad part 635, an overcoating layer 630, and a bank BNK′. Therefore, repeated descriptions of the identical components will be omitted.

First, with reference to FIG. 11, holes may be formed in the passivation layer 124, the overcoating layer 630, and the bank BNK′ and filled with the bonding member 175 so that the passivation layer 124, the overcoating layer 630, and the bank BNK′ are bonded to the flexible film 170. In this case, a size of the hole disposed in the passivation layer 124 may be smaller than a size of each of the holes formed in the overcoating layer 630 and the bank BNK′. More specifically, one end of each of the holes formed in the overcoating layer 630 and the bank BNK′ may be spaced apart from and positioned inward of the end of the first substrate 110 at a predetermined distance, and the other end of the hole may be coincident with the end of the adhesive layer 140. Therefore, an inner side surface of one of the holes formed in the passivation layer 124, the overcoating layer 630, and the bank BNK′ may have a stepped shape. Therefore, the holes formed in the overcoating layer 630 and the bank BNK′ may each be formed to have a width larger than a width of each of the holes formed in the overcoating layer 130 and the bank BNK of the display device 100 illustrated in FIG. 5A. Therefore, the hole having a large size is filled with the bonding member 175 at the time of bonding the flexible film 170 to the first substrate 110, which may more effectively suppress the overflow of the bonding member 175 in the direction of the display area AA.

The pad part 635 may be disposed along the inner side surface of the hole. The contact hole formed in the passivation layer 124 may be filled with the pad part 635, such that the pad part 635 may be disposed along the inner side surface of the hole formed in the overcoating layer 630 by a height of the overcoating layer 630. For example, in one embodiment, the pad part 635 does not extend upwardly beyond the overcoating layer 630. That is, because a size of each of the holes formed in the overcoating layer 630 and the bank BNK′ is larger than a size of the contact hole formed in the passivation layer 124, the pad part 635 may be disposed in a stepped shape. A process of disposing the pad part 635 will be briefly described. A contact hole having a first width is formed in the passivation layer 124 so that a top surface of the additional gate pattern GAT′ is exposed, and then a hole having a second width larger than the first width is formed as the overcoating layer 630 comes into contact with an end of the adhesive layer 140. Further, the pad part 635 is formed along the inner side surface of each of the holes formed in the top surface of the additional gate pattern GAT′ and the overcoating layer 630 at the same time when the anode AN of the display area AA is formed.

In the display device 600 according to a further example embodiment of the present disclosure, the size of each of the holes in the overcoating layer 630 and the bank BNK′, which are filled with the bonding member 175, may increase, which may minimize the overflow of the bonding member 175. Therefore, as illustrated in FIG. 11, the holes in the overcoating layer 630 and the bank BNK′ are filled with the bonding member 175, and the bonding member 175 may be spaced apart from the second substrate 150 and the blocking film 190. Therefore, in the display device 600 according to a further example embodiment of the present disclosure, it is possible to more assuredly ensure electrical insulation between the bonding member 175 and the second substrate 150.

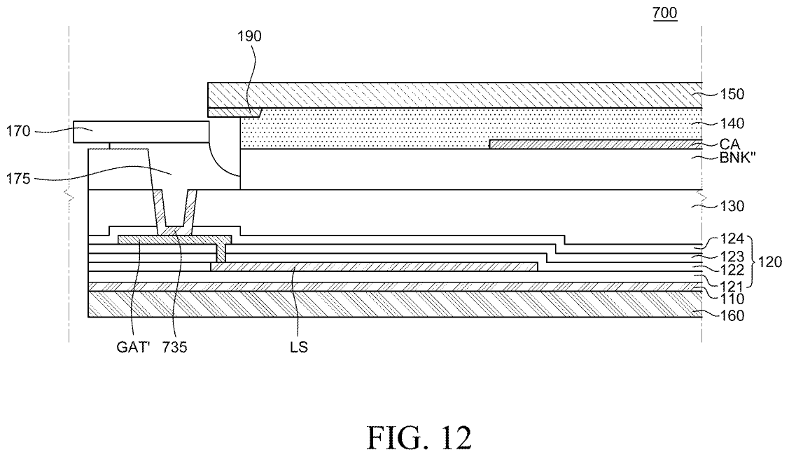

FIG. 12 is a cross-sectional view of a display device according to another further example embodiment of the present disclosure. A display device 700 in FIG. 12 is substantially identical in configuration to the display device 600 in FIG. 11, except for a pad part 735 and a bank BNK″. Therefore, repeated descriptions of the identical components will be omitted.

With reference to FIG. 12, holes may be formed in the passivation layer 124, the overcoating layer 130, and the bank BNK″ and filled with the bonding member 175 so that the passivation layer 124, the overcoating layer 630, and the bank BNK′ are bonded to the flexible film 170. In this case, the hole formed in bank BNK″ may have a larger size than each of the holes formed in the passivation layer 124 and the overcoating layer 130. More specifically, one end of each of the holes formed in the passivation layer 124, the overcoating layer 130, and bank BNK″ may be spaced apart from and positioned inward from the end of the first substrate 110 at a predetermined distance. Only the other end of the hole formed in the bank BNK″ may be coincident with the end of the adhesive layer 140, and an end of each of the holes formed in the passivation layer 124 and the overcoating layer 130 may be positioned outward of the end of the adhesive layer 140. Therefore, the hole formed in bank BNK″ may have a larger width than the hole formed in the bank BNK of the display device 100 illustrated in FIG. 5A. In addition, the contact hole formed in the passivation layer 124 may be filled with the pad part 735, such that the pad part 735 may be disposed along the inner side surface of the hole formed in the overcoating layer 130 by a height of the overcoating layer 130.

In the display device 700 according to a further example embodiment of the present disclosure, the size of each of the holes in the overcoating layer 130 and the bank BNK″, which are filled with the bonding member 175, may increase, which may minimize the overflow of the bonding member 175. Therefore, as illustrated in FIG. 12, the holes in the overcoating layer 130 and the bank BNK′ are filled with the bonding member 175, and the bonding member 175 may be spaced apart from the second substrate 150 and the blocking film 190. Therefore, in the display device 700 according to a further example embodiment of the present disclosure, it is possible to more assuredly ensure electrical insulation between the bonding member 175 and the second substrate 150.

The example embodiments of the present disclosure can also be described as follows:

According to an aspect of the present disclosure, a display device includes: a first substrate having a display area including a plurality of subpixels, and a non-display area; at least one flexible film at one end of the non-display area of the first substrate and electrically connected to the first substrate; a bonding member on the first substrate, including a conductive adhesive material, and bonding the first substrate and the flexible film; a second substrate above the first substrate, configured to expose the flexible film and the bonding member to the outside, and including a metallic material; an adhesive layer between the first substrate and the second substrate; and a blocking film on a lower surface of the second substrate and including an insulating material.

The blocking film may be disposed between the bonding member and the second substrate.

The blocking film may contact the bonding member.

The blocking film may be disposed to correspond to the bonding member.

The blocking film 190 may be disposed on the second substrate so as to have a width W2 corresponding to a boundary of a routing line 596 disposed in the non-display area of the first substrate in a plan view.

The blocking film may be disposed on the second substrate so as to have a width corresponding to a boundary of the flexible film in a plan view.

The blocking film may be disposed along one end of the second substrate correspond to the one end of the first substrate electrically connected to the flexible film in a plan view.

The blocking film may be disposed to overlap the adhesive layer in a cross-sectional view.

The blocking film may be disposed to be in contact with an end of the adhesive layer in a cross-sectional view.

The blocking film may be disposed on a front surface of the second substrate.

The display device may further include: an inorganic insulation layer in the non-display area of the first substrate and including a plurality of insulation layers; an overcoating layer on the inorganic insulation layer; and a bank on the overcoating layer. Holes may be disposed in an insulation layer, which is an uppermost layer of the inorganic insulation layer, the overcoating layer, and the bank, and the holes may be filled with the bonding member.

A pad part, which is electrically connected to the flexible film, may be disposed in the hole, and the pad part may be disposed along an inner side surface of the hole and disposed in the hole by a height of the overcoating layer.

The display device may further include: an additional bank on the bank and disposed in a space between the flexible film and the adhesive layer.

One end of the additional bank may be disposed to be closer to the display area than the flexible film, and the other end of the additional bank may be disposed to correspond to an end of the adhesive layer.

A size of each of the holes formed in the insulation layer, which is the uppermost layer, and the overcoating layer may be different from a size of the hole formed in the bank.

A size of the hole formed in the bank may be larger than a size of each of the holes formed in the insulation layer, which is the uppermost layer, and the overcoating layer.

A size of the hole formed in the insulation layer, which is the uppermost layer, may be different from a size of each of the holes formed in the overcoating layer and the bank.

A size of each of the holes formed in the overcoating layer and the bank may be larger than a size of the hole formed in the insulation layer which is the uppermost layer.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first body having a first substrate and a display area and a non-display area on the first substrate, the display area including a plurality of subpixels;
a flexible film on an end of the non-display area and electrically connected to the non-display area;
a bonding member on the first body, including a conductive adhesive material, and bonding the first body and the flexible film;
a second substrate on the first body, the flexible film and the bonding member at least partially exposed from the second substrate, and the second substrate including a metallic material;
an adhesive layer between the first body and the second substrate; and
a blocking film on a lower surface of the second substrate that faces the first body, the blocking film including an insulating material.

2. The display device of claim 1, wherein the blocking film is disposed between the bonding member and the second substrate.

3. The display device of claim 2, wherein the blocking film contacts the bonding member.

4. The display device of claim 2, wherein the blocking film is disposed corresponding to the bonding member.

5. The display device of claim 2, wherein the blocking film is disposed on the second substrate and has a width corresponding to a boundary of a routing line disposed in the non-display area in a plan view.

6. The display device of claim 2, wherein the blocking film is disposed on the second substrate and has a width corresponding to a boundary of the flexible film in a plan view.

7. The display device of claim 2, wherein the blocking film is disposed along an end of the second substrate correspond to the end of the non-display area connected to the flexible film in a plan view.

8. The display device of claim 2, wherein the blocking film overlaps the adhesive layer in a cross-sectional view.

9. The display device of claim 2, wherein the blocking film is in contact with an end of the adhesive layer in a cross-sectional view.

10. The display device of claim 2, wherein the blocking film is disposed on an entire area of the surface of the second substrate that faces the first body.

11. The display device of claim 1, further comprising:
an inorganic insulation layer in the non-display area of the first substrate and including a plurality of insulation layers;
an overcoating layer on the inorganic insulation layer; and
a bank on the overcoating layer, and
a hole in the bank, the overcoating layer, and an uppermost layer of the inorganic insulation layer,
wherein the bonding member extends in the hole.

12. The display device of claim 11, comprising a pad part in the hole, wherein the pad part is electrically connected to the flexible film, and the pad part is disposed along an inner side surface of the hole.

13. The display device of claim 12, wherein the pad part is disposed in the hole by a height of the overcoating layer.

14. The display device of claim 11, further comprising:
an additional bank on the bank and disposed in a space between the flexible film and the adhesive layer.

15. The display device of claim 14, wherein an end of the additional bank is disposed to be closer to the display area than the flexible film, and another end of the additional bank is disposed corresponding to an end of the adhesive layer.

16. The display device of claim 12, wherein the hole has a first dimension in the uppermost layer of the inorganic insulation layer, a second dimension in the overcoating layer, and a third dimension in the bank, the first dimension and the second dimension each being different from the third dimension.

17. The display device of claim 16, wherein the third dimension of the hole is larger than each of the first dimension or the second dimension of the hole.

18. The display device of claim 16, wherein the first dimension of the hole is different from each of the second dimension or the third dimension of the hole.

19. The display device of claim 18, wherein the first dimension of the hole is smaller than each of the second dimension or the third dimension of the hole.

20. A display device comprising:
a first body;
a flexible film on the first body;
a bonding member between the first body and the flexible film;
a second body on the first body, the second body including a metallic material;
an adhesive layer between the first body and the second body,
an undercut region positioned between the second body and the first body; and
a blocking film on a surface of the second body adjacent to the undercut region, the blocking film including an insulating material.
